(19) United States
(12) Patent Application Publication
(10) Pub. No.: US 2022/0376053 A1
(43) Pub. Date: Nov. 24, 2022

(54) SEMICONDUCTOR DEVICE AND MANUFACTURING METHOD THEREOF

(71) Applicant: INNOSCIENCE (ZHUHAI) TECHNOLOGY CO., LTD., ZHUHAI CITY (CN)

(72) Inventors: KING YUEN WONG, ZHUHAI CITY (CN); KYE JIN LEE, ZHUHAI CITY (CN)

(21) Appl. No.: 17/048,617

(22) PCT Filed: Jun. 4, 2020
(86) PCT No.: PCT/CN2020/094413

§ 371 Date: Oct. 19, 2020

(51) Int. Cl. H01L 29/15; H01L 29/20; H01L 29/205; H01L 29/207; H01L 29/40; H01L 29/778; H01L 21/02

(52) U.S. Cl. CPC H01L 29/157; H01L 29/2003; H01L 29/205; H01L 29/207; H01L 29/402; H01L 29/7785; H01L 21/02458; H01L 21/02507

(57) ABSTRACT

Embodiments of the present application disclose a semiconductor device and a manufacturing method thereof. The semiconductor device includes a semiconductor layer, a first doped nitride semiconductor layer disposed on the semiconductor layer, and a second doped nitride semiconductor layer disposed on the first doped nitride semiconductor layer. The semiconductor device further includes an undoped nitride semiconductor layer between the semiconductor layer and the first doped nitride semiconductor layer. The undoped nitride semiconductor layer has a first surface in contact with the semiconductor layer and a second surface in contact with the first doped nitride semiconductor layer.

### BACKGROUND OF THE INVENTION

### 1. Field of the Invention

The present disclosure relates to a semiconductor device and a manufacturing method thereof, and in particular, to a semiconductor device with a superlattice layer, a doped group III-V semiconductor layer, and an undoped group III-V semiconductor layer and a manufacturing method thereof.

### 2. Description of the Related Art

Components including a direct bandgap semiconductor, such as a semiconductor component including group III-V materials or group III-V compounds can operate or work under various conditions or environments (such as different voltages and frequencies) due to their characteristics.

The above semiconductor component may include a heterojunction bipolar transistor (HBT), a heterojunction field effect transistor (HFET), a high-electron-mobility transistor (HEMT) or a modulation-doped FET (MODFET), etc.

### SUMMARY OF THE INVENTION

Some embodiments of the present disclosure provide a semiconductor device, including a semiconductor layer, a first doped nitride semiconductor layer disposed on the semiconductor layer, and a second doped nitride semiconductor layer disposed on the first doped nitride semiconductor layer. The semiconductor device further includes an undoped nitride semiconductor layer between the semiconductor layer and the first doped nitride semiconductor layer. The undoped nitride semiconductor layer has a first surface in contact with the semiconductor layer and a second surface in contact with the first doped nitride semiconductor layer.

Some embodiments of the present disclosure provide a manufacturing method of a semiconductor device. The method includes: forming a semiconductor layer on a substrate. The semiconductor layer has a top layer. The method further includes: forming an undoped nitride semiconductor layer on the top layer of the semiconductor layer and forming a doped nitride semiconductor layer on the undoped nitride semiconductor layer.

### BRIEF DESCRIPTION OF THE DRAWINGS

The aspects of the present disclosure will become more comprehensible from the following detailed implementations made with reference to the accompanying drawings. It should be noted that various features may not be drawn to scale. In fact, the sizes of the various features may be increased or reduced arbitrarily for the purpose of clear description.

FIG. 1 shows a side view of a semiconductor device in accordance with some embodiments of the present disclosure;

FIG. 2 shows a partial enlarged view of a semiconductor device in accordance with some embodiments of the present disclosure; and

FIG. 3A, FIG. 3B, and FIG. 3C show a plurality of operations for manufacturing a semiconductor device in accordance with some embodiments of the present disclosure.

### PREFERRED EMBODIMENT OF THE PRESENT INVENTION

The following disclosed content provides many different embodiments or examples of different features for implementing the provided subject matters. Specific examples of components and arrangements are described below. Certainly, these are merely examples and are not intended to be limiting. In the present disclosure, in the following descriptions, the description of the first feature being formed on or above the second feature may include an embodiment formed by direct contact between the first feature and the second feature, and may further include an embodiment in which an additional feature may be formed between the first feature and the second feature so that the first feature and the second feature are not in direct contact. In addition, in the present disclosure, reference numerals and/or letters may be repeated in examples. The repetition is for the purpose of simplification and clarity, and does not in itself dictate a relationship between the various embodiments and/or configurations discussed.

The embodiments of the present disclosure are described in detail below. It should be appreciated, however, that the present disclosure provides many applicable concepts that can be embodied in a wide variety of specific contexts. The described specific embodiments are merely illustrative and do not limit the scope of the present disclosure.

Direct bandgap materials, for example, III-V compounds, may include but are not limited to gallium arsenide (GaAs), indium phosphide (InP), gallium nitride (GaN), indium gallium arsenide (InGaAs), aluminum gallium arsenide (AlGaAs), etc.

For a semiconductor device (for example, a high electron mobility transistor (HEMT)) using III-V group compounds, one method for improving a leakage current blocking capability (that is, improving a breakdown voltage) is to introduce a carbon-doped III-V semiconductor layer in the semiconductor device. Although introducing carbon-doped III-V semiconductor layer may improve the leakage current blocking capability, the overall size of the semiconductor device or structure may be increased, defects (for example, delamination or peeling-off) caused by different material between adjacent layers need to be taken into consideration, and costs may be increased.

In addition, because the lattice arrangement of the carbon-doped III-V semiconductor layer is relatively loose compared to other semiconductor layers (for example, a superlattice layer) in the device, diffusion of crystallographic defect (for example, a dislocation) generated in a relatively high voltage environment (for example, greater than 200 volts (V)) may not be effectively prevented.

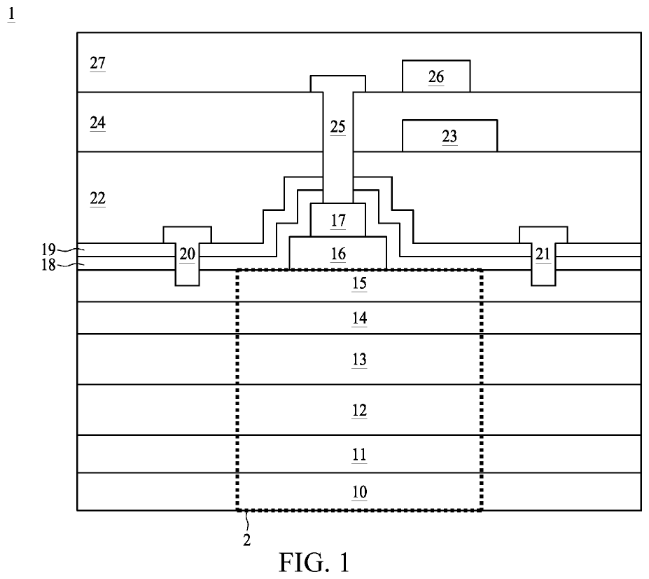

FIG. 1 shows a side view of a semiconductor device 1 in accordance with some embodiments of the present disclosure.

As shown in FIG. 1, the semiconductor device may include a substrate 10, a semiconductor layer 11, an undoped group III-V semiconductor layer 12, a doped group III-V semiconductor layer 13, a group III-V semiconductor layer 14, a group III-V semiconductor layer 15, a doped group III-V semiconductor layer 16, a metal layer 17, a passivation layer 18, a passivation layer 19, a source contact 20, a drain contact 21, a dielectric layer 22, a field plate 23, a dielectric layer 24, a conductor structure 25, a field plate 26, and a dielectric layer 27.

The substrate 10 may include, for example but not limited to, silicon (Si), doped silicon (doped Si), silicon carbide (SiC), silicon germanium (SiGe), gallium arsenide (GaAs), or other semiconductor materials. The substrate 10 may include, for example but not limited to, sapphire, silicon on insulator (SOI), or other suitable materials.

The semiconductor layer 11 may be disposed on the substrate 10. The semiconductor layer 11 may be disposed between the substrate 10 and the undoped III-V semiconductor layer 12.

In some embodiments, the semiconductor layer 11 may include a buffer layer. In some embodiments, the semiconductor layer 11 may include, for example but not limited to, a superlattice layer. In some embodiments, the semiconductor layer 11 may include, for example but not limited to, nitrides, for example, aluminum nitride (AlN) and aluminum gallium nitride (AlGaN). In some embodiment, the semiconductor layer 11 may be configured to improve lattice match between the substrate 10 and layers (for example, the undoped group III-V semiconductor layer 12 and/or the doped group III-V semiconductor layer 13 above the substrate 10) on the substrate 10. The semiconductor layer 11 may include a multi-layer structure. The semiconductor layer 11 may include a multi-layer stack. The semiconductor layer 11 may include, for example but not limited to, a plurality of GaN layers and a plurality of AlGaN layers that are stacked alternatively. In some embodiments, the semiconductor layer 11 may reduce a tensile stress of the semiconductor device 1. In some embodiments, the semiconductor layer 11 may capture electrons that diffuse from the substrate 10 to the undoped group III-V semiconductor layer 12 and/or the doped group III-V semiconductor layer 13, thereby improving device performance and reliability. In some embodiments, the semiconductor layer 11 may improve a breakdown voltage. In some embodiments, the semiconductor layer 11 may prevent defects (for example, a dislocation) from propagating from the substrate 10 to the undoped group III-V semiconductor layer 12 and/or the doped group III-V semiconductor layer 13, thereby avoiding the dysfunction of the semiconductor device 1.

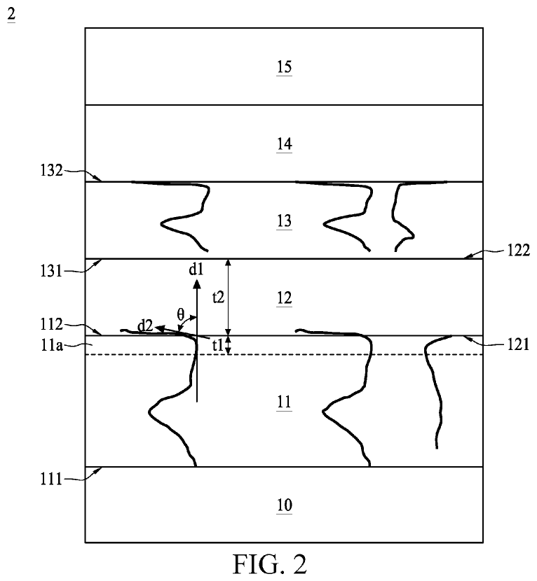

The undoped III-V semiconductor layer 12 may be disposed on the semiconductor layer 11. In other words, the undoped group III-V semiconductor layer 12 may be arrange between the semiconductor layer 11 is and the doped group III-V semiconductor layer 13. In some embodiments, a lattice density of the undoped group III-V semiconductor layer 12 may greater than that of the semiconductor layer 11. In some embodiments, the lattice density of the undoped group III-V semiconductor layer 12 may greater than that of the doped group III-V semiconductor layer 13. For a detailed structure of the undoped group III-V semiconductor layer 12, reference may be made to FIG. 2 described later.

In some embodiments, the undoped group III-V semiconductor layer 12 may include, for example but not limited to, gallium arsenide (GaAs), indium phosphide (InP), gallium nitride (GaN), indium gallium arsenide (InGaAs), and aluminum gallium arsenide (AlGaAs). In some embodiments, the undoped group III-V semiconductor layer 12 may include a nitride semiconductor layer. In some embodiments, the undoped group III-V semiconductor layer 12 may include, for example but not limited to, a III nitride such as a compound InₓAl_{y}Ga_{1-x-y}N, where x+y≤1 and a compound Al_{y}Ga_{(1-y)}N, where y≤1. In some embodiments, the undoped group III-V semiconductor layer 12 may include, for example but not limited to, two-dimensional (2D) materials. In some embodiments, the undoped group III-V semiconductor layer 12 may include, for example but not limited to, crystalline materials consisting of a single layer of atoms.

The doped group III-V semiconductor layer 13 may be disposed on the undoped group III-V semiconductor layer 12. In some embodiments, the doped group III-V semiconductor layer 13 may include a nitride semiconductor layer. In some embodiments, the doped group III-V semiconductor layer 13 may include, for example but not limited to, doped gallium nitride (doped GaN), doped aluminum gallium nitride (doped AlGaN), doped indium gallium nitride (doped InGaN), and other doped III-V compounds. In some embodiments, the doped group III-V semiconductor layer 13 may include, for example but not limited to, a p-type dopant, an n-type dopant, or other dopants. In some embodiments, the dopants of the doped group III-V semiconductor layer 13 may include, for example but not limited to, carbon (C), silicon (Si), and germanium (Ge). In some is embodiments, the doped group III-V semiconductor layer 13 may include, for example but not limited to, a carbon-doped III-V semiconductor layer.

The doped group III-V semiconductor layer 13 may improve a leakage current blocking capability, however, the lattice arrangement of the doped group III-V semiconductor layer 13 is relatively loose compared to other semiconductor layers (for example, the semiconductor layer 11) of the semiconductor device 1. When the semiconductor device 1 is applied in a relatively high voltage environment (for example, greater than 200V), a crystallographic defect (for example, a dislocation) may diffuse from the semiconductor layer 11 through the doped group III-V semiconductor layer 13 to the group III-V semiconductor layer 14 and the group III-V semiconductor layer 15 (the group III-V semiconductor layer 14 and the group III-V semiconductor layer 15 are described later), resulting in the dysfunction of the semiconductor device 1.

According to the present disclosure, by arranging the undoped group III-V semiconductor layer 12 between the doped group III-V semiconductor layer 13 and the semiconductor layer 11, a defect density may be reduced without excessively increasing the overall thickness (for example, the overall thickness is increased by less than 10%) of the device. For example, a dislocation density of the undoped group III-V semiconductor layer 12 disposed between the semiconductor layer 11 and the doped group III-V semiconductor layer 13 diffusing or propagating to the group III-V semiconductor layer 14 and the group III-V semiconductor layer 15 through the doped group III-V semiconductor layer 13 may be reduced. For example, a dislocation density of the undoped group III-V semiconductor layer 12 disposed between the semiconductor layer 11 and the doped group III-V semiconductor layer 13 diffusing or propagating from the semiconductor layer 11 to the group III-V semiconductor layer 14 and the group III-V semiconductor layer 15 through the doped group III-V semiconductor layer 13 may be reduced. For example, a dislocation density of the undoped group III-V semiconductor layer 12 disposed between the semiconductor layer 11 and the doped group III-V semiconductor layer 13 diffusing or propagating is from the semiconductor layer 11 to the group III-V semiconductor layer 14 and the group III-V semiconductor layer 15 through the doped group III-V semiconductor layer 13 may be reduced by at least one order of magnitude. For example, the undoped group III-V semiconductor layer 12 disposed between the semiconductor layer 11 and the doped group III-V semiconductor layer 13 may cause the semiconductor device 1 to operate under the high voltage environment (for example, greater than 200 V).

The group III-V semiconductor layer 14 may be disposed on the doped group III-V semiconductor layer 13. In some embodiments, the group III-V semiconductor layer 14 may include, for example but not limited to, an undoped group III-V semiconductor layer. The group III-V semiconductor layer 14 may include, for example but not limited to, GaAs, InP, GaN, InGaAs, and AlGaAs. In some embodiments, the group III-V semiconductor layer 14 may include a nitride semiconductor layer. The group III-V semiconductor layer 14 may include, for example but not limited to, a group III nitride such as a compound InₓAl_{y}Ga_{1-x-y}N, where x+y<1. The group III nitride may further include, for example but not limited to, a compound Al_{y}Ga_{(1-y)}N, where y<1.

The group III-V semiconductor layer 15 may be disposed on the doped group III-V semiconductor layer 13. The group III-V semiconductor layer 15 may be disposed on the III-V semiconductor layer 14. In some embodiments, the group III-V semiconductor layer 15 may include a nitride semiconductor layer. In some embodiments, the group III-V semiconductor layer 15 may include, for example but not limited to, a group III nitride such as a compound InₓAl_{y}Ga_{1-x-y}N, where x+y<1. The group III-V semiconductor layer 15 may include, for example but not limited to, a compound Al_{y}Ga_{(1-y)}N, where y<1.

The group III-V semiconductor layer 15 may have a bandgap relatively larger than the bandgap of the group III-V semiconductor layer 14. For example, the group III-V semiconductor layer 14 may include a GaN layer, and the GaN may have a bandgap of about 3.4 electron volt (eV). The group III-V semiconductor layer 15 may include AlGaN, and the AlGaN may have is a bandgap of about 4.0 eV. A heterojunction is formed between the group III-V semiconductor layer 14 and the group III-V semiconductor layer 15, and polarization of heterojunctions of different nitrides is formed. An electron channel area (for example, a two-dimensional electron gas (2DEG) area) may be formed in the group III-V semiconductor layer 14. The group III-V semiconductor layer 14 may be used as a channel layer of the semiconductor device 1, and the group III-V semiconductor layer 15 may be used as a barrier layer of the semiconductor device 1.

The doped group III-V semiconductor layer 16 may be disposed on the III-V semiconductor layer 15. In some embodiments, the doped group III-V semiconductor layer 16 may include, for example but not limited to, doped GaN, doped AlGaN, doped InGaN, and other doped group III-V compounds. In some embodiments, the doped group III-V semiconductor layer 16 may include a doped nitride semiconductor layer. In some embodiments, the doped group III-V semiconductor layer 16 may include, for example but not limited to, a p-type dopant or other dopants. In some embodiments, the dopants of the doped group III-V semiconductor layer 16 may include, for example but not limited to, magnesium (Mg), zinc (Zn), cadmium (Cd), silicon (Si), germanium (Ge), etc.

The metal layer 17 may be disposed on the doped group III-V semiconductor layer 16. In some embodiments, the metal layer 17 may include, for example but not limited to, a refractory metal or other compounds. The metal layer 17 may include, for example but not limited to, metals such as niobium (Nb), molybdenum (Mo), tantalum (Ta), wolfram (W), rhenium (Re), titanium (Ti), vanadium (V), chromium (Cr), zirconium (Zr), hafnium (Hf), ruthenium (Ru), osmium (Os), and iridium (Ir) and compounds of such metals, for example, tantalum nitride (TaN), titanium nitride (TiN), and wolfram carbide (WC).

In some embodiments, the metal layer 17 may be used as a stop layer or a protective layer of the doped group III-V semiconductor layer 16 in a manufacturing process of the semiconductor device 1. For example, the metal layer 17 may cause an unexposed surface of the doped group III-V semiconductor layer 16 to maintain substantially relatively flat during use of a removal technology (for example, an etching technology). In some embodiments, the metal layer 17 can help to improve bias voltage control of the conductor structure 25. In some embodiments, the metal layer 17 can help to improve a switching speed of a gate. In some embodiments, the metal layer 17 can help to reduce a leakage current and improve a threshold voltage.

The conductor structure 25 may be disposed on the metal layer 17. In some embodiments, the conductor structure 25 may include, for example but not limited to, a gate structure. In some embodiments, the conductor structure 25 may include, for example but not limited to, gate metals. In some embodiments, the gate metals of the conductor structure 25 may include, for example but not limited to, titanium (Ti), tantalum (Ta), wolfram (W), aluminum (Al), cobalt (Co), copper (Cu), nickel (Ni), platinum (Pt), plumbum (Pb), molybdenum (Mo) and compounds thereof (for example but not limited to, titanium nitride (TiN), tantalum nitride (TaN), other conductive nitrides, or conductive oxides), metal alloys (such as aluminum copper (Al—Cu)), or other suitable materials.

The passivation layer 18 may be disposed on the group III-V semiconductor layer 15. The passivation layer 18 may surround the doped group III-V semiconductor layer 16. The passivation layer 18 may cover the doped group III-V semiconductor layer 16. The passivation layer 18 may surround the metal layer 17. The passivation layer 18 may cover the metal layer 17. The passivation layer 18 may cover a portion of the metal layer 17. The passivation layer 18 may surround the conductor structure 25. The passivation layer 18 may surround a portion of the conductor structure 25. In some embodiments, the passivation layer 18 may include, for example but not limited to, oxides or nitrides. In some embodiments, the passivation layer 18 may include, for example but not limited to, silicon nitride (Si₃N₄), silicon oxide (SiO₂), or other suitable materials. In some embodiments, the passivation layer 18 may include, for example but not limited to, composite layers of oxides and nitrides, for example, Al₂O₃/Si₃N₄, Al₂O₃/SiO, AlN/Si₃N₄, and AlN/SiO₂

The passivation layer 19 may be disposed on the passivation layer 18. The passivation layer 19 may surround the conductor structure 25. The passivation layer 19 may surround a portion of the conductor structure 25. In some embodiments, the passivation layer 19 may include, for example but not limited to, the foregoing listed materials of the passivation layer 18.

The source contact 20 may be disposed on the group III-V semiconductor layer 15. The source contact 20 may penetrate through the passivation layer 18 and the passivation layer 19 and make contact with the group III-V semiconductor layer 15. The source contact 20 may be locally located in the group III-V semiconductor layer 15. In some embodiments, the source contact 20 may include, for example but not limited to, conductor materials. In some embodiments, the source contact 20 may include, for example but not limited to, metals, alloys, doped semiconductor materials (for example, doped crystalline silicon), or other suitable conductor materials.

The drain contact 21 may be disposed on the group III-V semiconductor layer 15. The drain contact 21 may penetrate through the passivation layer 18 and the passivation layer 19 and make contact with the group III-V semiconductor layer 15. The drain contact 21 may be locally located in the group III-V semiconductor layer 15. In some embodiments, the drain contact 21 may include, for example but not limited to, the foregoing listed materials of the source contact 20.

Although the source contact 20 and the drain contact 21 are respectively disposed at two sides of the conductor structure 25 in FIG. 1, the locations of the source contact 20, the drain contact 21, and the conductor structure 25 may have different configurations in other embodiments of the present disclosure due to design requirements.

The dielectric layer 22 may be disposed on the passivation layer 19. The dielectric layer 22 may surround the conductor structure 25. The dielectric layer 22 may surround a portion of the conductor structure 25. The dielectric layer 22 may cover the source contact 20. The dielectric layer 22 may cover the drain contact 21. In some embodiments, the dielectric layer 22 may include, for example but not limited to, the foregoing listed materials of the passivation layer 18. In some embodiments, the dielectric layer 22 may include materials different from the materials of the passivation layer 18 and/or the passivation layer 19, for example, other dielectric materials.

The field plate 23 may be disposed on the dielectric layer 22. The field plate 23 may be adjacent to the conductor structure 25. The field plate 23 may be connected to the source contact 20 and/or the drain contact 21 through other conductor structures. In some embodiments, the field plate 23 may include, for example but not limited to, conductor materials, for example, metals or alloys.

The dielectric layer 24 may be disposed on the dielectric layer 22 and cover the field plate 23. The dielectric layer 24 may surround the conductor structure 25. The dielectric layer 24 may surround a portion of the conductor structure 25. In some embodiments, the dielectric layer 24 may include, for example but not limited to, the foregoing listed materials of the passivation layer 18.

The field plate 26 may be disposed on the dielectric layer 24. The field plate 26 may be separated from the field plate 23 through the dielectric layer 24. The field plate 26 may be adjacent to the conductor structure 25. The projected areas of the field plate 26 and the field plate 23 on the substrate 10 may at least partially overlapped. The field plate 26 may be connected to the source contact 20 and/or the drain contact 21 through other conductor structures. In some embodiments, the field plate 26 may include, for example but not limited to, conductor materials, for example, metals or alloys.

The dielectric layer 27 may be disposed on the dielectric layer 24 and cover the field plate 26. The dielectric layer 27 may cover a portion of the conductor structure 25. In some embodiments, the dielectric layer 27 may include, for example but not limited to, the foregoing listed materials of the passivation layer 18.

Although the semiconductor device 1 has three dielectric layers (the dielectric layer 22, the dielectric layer 24, and the dielectric layer 27) according to the description of the present disclosure, the present disclosure is not limited thereto. For example, in some embodiments, the semiconductor device 1 may have any quantity of dielectric layers according to device specifications. Although the semiconductor device 1 has two layers of field plates (the field plate 23 and the field plate 26) according to the description of the present disclosure, the present disclosure is not limited thereto. For example, in some embodiments, the semiconductor device 1 may have any quantity of field plates according to device specifications.

FIG. 2 shows a partial enlarged view of a semiconductor device in accordance with some embodiments of the present disclosure. In some embodiments, a portion 2 of a semiconductor device shown in FIG. 2 may be a portion of a semiconductor device 1 shown in FIG. 1.

The semiconductor layer 11 may have a surface 111 in contact with the substrate 10. The semiconductor layer 11 may have a surface 112 in contact with the undoped group III-V semiconductor layer 12. The semiconductor layer 11 may include a multi-layer structure and/or a multi-layer stack. The semiconductor layer 11 may include a multi-layer structure and/or a multi-layer stack that are/is composed of two compounds. The semiconductor layer 11 may include a multi-layer structure and/or a multi-layer stack that are/is formed by alternatively stacking two compounds. In some embodiments, each layer of the semiconductor layer 11 may include, for example but not limited to, a plurality of layers having a thickness at a nanometer (nm) level. For example, the semiconductor layer 11 may include a plurality of layers with the thickness being about 1 nm to about 100 nm. For example, the semiconductor layer 11 may include a plurality of layers with the thickness being about 1 nm to about 50 nm. In some embodiments, interfaces between layers in the semiconductor layer 11 may be observed by using, for example, a transmission electron microscope (TEM). The foregoing interfaces are not drawn in the drawings for brevity. In some embodiments, the semiconductor layer 11 may include a top layer 11a. The top layer 11a may be a layer furthest from the substrate 10 of the layers in the semiconductor layer 11. In other words, the top layer 11a may be a layer closest to the undoped III-V semiconductor layer 12 of the layers in the semiconductor layer 11. In other words, the top layer 11a may have the surface 112. The top layer 11a may be a homogeneous layer, for example, the top layer 11a may have a single material. In some embodiments, the top layer 11a may have a substantially homogeneous concentration. In some embodiments, the top layer 11a may have a gradient concentration. The top layer 11a may make contact with the undoped group III-V semiconductor layer 12. The thickness of the top layer 11a may be indicated by “t1”. The thickness t1 of the top layer 11a may be measured in a direction substantially perpendicular to the surface 111 and/or a surface 121. In some embodiments, the thickness t1 of the top layer 11a may range from about 1 nm to about 100 nm, from about 1 nm to about 50 nm, or from about 1 nm to about 10 nm. In some embodiments, the top layer 11a may have the same material as the undoped group III-V semiconductor layer 12. In some embodiments, the material of the top layer 11a may be different from the material of the undoped group III-V semiconductor layer 12. In some embodiments, an interface between the top layer 11a and the undoped group III-V semiconductor layer 12, that is, an interface between the surface 112 and the surface 121, may be observed by using, for example, the TEM.

The undoped group III-V semiconductor layer 12 may have the surface 121 in contact with the semiconductor layer 11. The undoped group III-V semiconductor layer 12 may have a surface 122 in contact with the doped group III-V semiconductor layer 13. The thickness of the undoped group III-V semiconductor layer 12 may be indicated by “t2”. The thickness t2 of the undoped group III-V semiconductor layer 12 may be measured in a direction substantially perpendicular to the surface 121 and/or the surface 122. In some embodiments, the thickness t2 of the undoped group III-V semiconductor layer 12 may be greater than the thickness of each layer in the semiconductor layer 11. In some embodiments, the thickness t2 of the undoped group III-V semiconductor layer 12 may be greater than the thickness of each layer in the semiconductor layer 11 by at least one order of magnitude. For example, the thickness of each layer in the semiconductor layer 11 may be less than the thickness t2 of the undoped group III-V semiconductor layer 12 by at least one order of magnitude. For example, the thickness t2 of the undoped group III-V semiconductor layer 12 may be greater than the thickness t1 of the top layer 11a of the semiconductor layer 11. In some embodiments, the thickness t2 of the undoped group III-V semiconductor layer 12 may be greater than the thickness t1 of the top layer 11a by at least one order of magnitude. For example, the thickness t1 of the top layer 11a may be less than the thickness t2 of the undoped group III-V semiconductor layer 12 by at least one order of magnitude. In some embodiments, the thickness t2 of the undoped group III-V semiconductor layer 12 may be, for example but not limited to, an order of micrometer (μm). For example, the thickness of the undoped group III-V semiconductor layer 12 may range from about 0.01 μm to about 1 μm, that is, from about 10 nm to about 1000 nm.

In some embodiments, the interface between the top layer 11a and the undoped group III-V semiconductor layer 12 (that is, the interface between the surface 112 and the surface 121) may have a dislocation. In some embodiments, the dislocation located at the interface between the top layer 11a and the undoped III-V semiconductor layer 12 may extend substantially along the surface 121 of the undoped III-V semiconductor layer 12. In some embodiments, the dislocation located at the interface between the top layer 11a and the undoped group III-V semiconductor layer 12 may extend substantially along the surface 112 of the semiconductor layer 11. For example, as shown in FIG. 2, a dislocation of propagating substantially towards a direction (indicated by “d1) of the undoped III-V semiconductor layer 12 from the semiconductor layer 11 change a propagating direction to another direction (indicated by “d2”) at the interface between the top layer 11a and the undoped group III-V semiconductor layer 12. In some embodiments, a change angle (indicated by “0”, that is, an included angle between the direction d1 and the direction d2) of the propagating direction of the dislocation at the interface between the top layer 11a and the undoped group III-V semiconductor layer 12 may be at least 30 degrees, at least 37 degrees, at least 40 degrees, at least 50 degrees, at least 60 degrees, at least 70 degrees, or more, for example, may be 90 degrees.

In some embodiments, because the dislocation at the interface between the top layer 11a and the undoped group III-V semiconductor layer 12 changes the propagating direction, in some embodiments, a dislocation density at an interface between the undoped group III-V semiconductor layer 12 and the doped group III-V semiconductor layer 13 may be less than a dislocation density at an interface between the undoped group III-V semiconductor layer 12 and the semiconductor layer 11. In other words, a dislocation density at the surface 122 of the undoped group III-V semiconductor layer 12 may be less than a dislocation density at the surface 121 of the undoped group III-V semiconductor layer 12. In some embodiments, the dislocation density at the surface 122 of the undoped group III-V semiconductor layer 12 may be less than the dislocation density at the surface 121 of the undoped group III-V semiconductor layer 12 by at least one order of magnitude. In other words, the proportion of the dislocation density along the direction d2 at the interface between the top layer 11a and the undoped group III-V semiconductor layer 12 is at least ten percent of a total dislocation density. In some embodiments, all dislocations at the interface between the top layer 11a and the undoped group III-V semiconductor layer 12 change the propagating direction to the direction d2. Therefore, the dislocation density in the undoped group III-V semiconductor layer 12 may be about zero, in other words, the undoped III-V semiconductor layer 12 may have no dislocation.

In a comparative embodiment without the undoped group III-V semiconductor layer 12, the top layer 11a directly makes contact with the doped group III-V semiconductor layer 13. A change angle of the dislocation at an interface between the top layer 11a and the doped group III-V semiconductor layer 13 is less than 40 degrees, less than 37 degrees, less than 30 degrees, less than 20 degrees, or lower. In some embodiments, the dislocation hardly changes the propagating direction from the top layer 11a to the doped group III-V semiconductor layer 13.

Compared with the comparative embodiment, a dislocation density of the group III-V semiconductor layer 14 and a dislocation density of the group III-V semiconductor layer 15 are reduced by at least one order of magnitude. In addition, introducing the undoped group III-V semiconductor layer 12 may cause the overall thickness of a device (for example, the semiconductor device 1) to be increased by less than 10%. Therefore, introducing the undoped group III-V semiconductor layer 12 that is thicker than each layer in the semiconductor layer 11 does not cause a chip to bend during processing due to thermal mismatch or other stress effects.

The doped group III-V semiconductor layer 13 may have a surface 131 in contact with the undoped group III-V semiconductor layer 12. The doped group III-V semiconductor layer 13 may have a surface 132 in contact with the group III-V semiconductor layer 14. In some embodiments, the interface between the doped group III-V semiconductor layer 13 and the undoped group III-V semiconductor layer 12 (that is, the interface between the surface 122 and the surface 131) may have a dislocation. In some embodiments, the dislocation at the interface between the doped group III-V semiconductor layer 13 and the undoped group III-V semiconductor layer 12 may extend from the undoped group III-V semiconductor layer 12. In some embodiments, a change angle of the dislocation at the interface between the doped group III-V semiconductor layer 13 and the undoped group III-V semiconductor layer 12 may be about zero. In some embodiments, a dislocation density at the interface between the doped group III-V semiconductor layer 13 and the undoped group III-V semiconductor layer 12 may be about zero.

In some embodiments, introducing the undoped group III-V semiconductor layer 12 may cause a dislocation density on a doped group III-V semiconductor layer of a device (for example, the semiconductor device 1) to be reduced by at least one order of magnitude. For example, a threading dislocation density on the doped group III-V semiconductor layer 13 is reduced from about 10⁹ cm′ to 1×10⁸ cm′ to 5×10⁸ cm′. For example, a threading dislocation density on the group III-V semiconductor layer 14 is is reduced from about 10⁹ cm′ to 1×10⁸ cm′ to 5×10⁸ cm′. For example, a threading dislocation density on the group III-V semiconductor layer 15 is reduced from about 10⁹ cm′ to 1×10⁸ cm′ to 5×10⁸ cm′. For example, a threading dislocation density on the doped group III-V semiconductor layer 16 is reduced from about 10⁹ cm′ to 1×10⁸ cm′ to 5×10⁸ cm′.

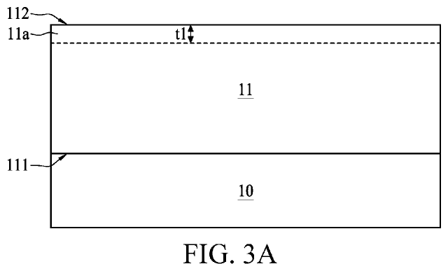

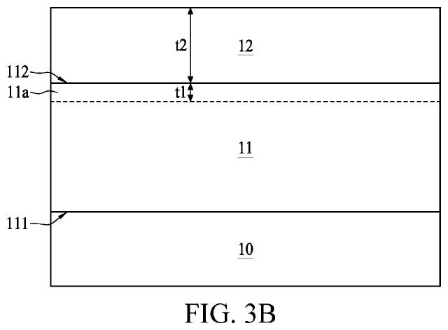

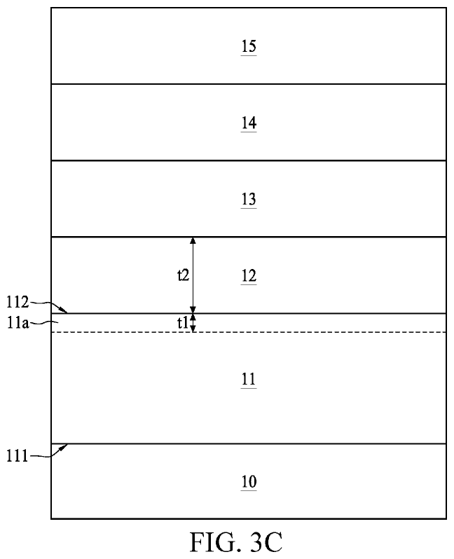

FIG. 3A, FIG. 3B, and FIG. 3C show a plurality of operations for manufacturing a semiconductor device in accordance with some embodiments of the present disclosure.

Referring to FIG. 3A, a substrate 10 is provided. Then, a semiconductor layer 11 is formed on the substrate 10. In some embodiments, the semiconductor layer 11, for example, may be formed through metal organic chemical vapor deposition (MOCVD), epitaxial growth, or other suitable deposition steps The semiconductor layer 11 may have a surface 111 in contact with the substrate 10 and a surface 112 opposite to the surface 111. The semiconductor layer 11 may include a plurality of layers with the thickness being about 1 nm to about 100 nm. For example, the semiconductor layer 11 may include a plurality of layers with the thickness being about 1 nm to about 50 nm. For example, the semiconductor layer 11 may include a top layer 11a. The thickness t1 of the top layer 11a may range from about 1 nm to about 100 nm, from about 1 nm to about 50 nm, or from about 1 nm to about 10 nm.

Referring to FIG. 3B, an undoped group III-V semiconductor layer 12 is formed on the top layer 11a. In some embodiments, the undoped group III-V semiconductor layer 12, for example, may be formed through chemical vapor deposition (CVD), high density plasma (HDP) CVD, physical vapor deposition (PVD), epitaxial growth, spin-on, sputtering, etc. The thickness of the undoped group III-V semiconductor layer 12 may be indicated by “t2”. For example, the thickness t2 of the undoped III-V semiconductor layer 12 may range from about 0.01 μm to about 1 μm, that is, from about 10 nm to about 1000 nm.

Referring to FIG. 3C, a doped group III-V semiconductor layer 13, a group III-V semiconductor layer 14, and a group III-V semiconductor layer is 15 are formed on the undoped group III-V semiconductor layer 12. In some embodiments, the doped group III-V semiconductor layer 13 may be deposited on the undoped group III-V semiconductor layer 12. In some embodiments, the group III-V semiconductor layer 14 may be deposited on the doped group III-V semiconductor layer 13. In some embodiments, the group III-V semiconductor layer 15 may be deposited on the group III-V semiconductor layer 14.

Subsequently, a doped group III-V semiconductor layer 16 and a metal layer 17 shown in FIG. 1 may be formed on the group III-V semiconductor layer 15. Subsequently, passivation layers (for example, the passivation layer 18 and the passivation layer 19 shown in FIG. 1) may be formed through CVD, HDPCVD, spin-on, sputtering, etc. In some embodiments, an opening may be formed by one or more etching processes, and a conductive material may be filled into the opening by deposition steps such as CVD, PVD, and electroplating to form a source contact and a drain contact (for example, the source contact 20 and the drain contact 21 shown in FIG. 1). In some embodiments, dielectric layers 22, 24, and 27 shown in FIG. 1 may be formed on the passivation layer. In some embodiments, the dielectric layers 22, 24, and 27 may be deposited in the following manners: CVD, HDPCVD, spin-on, sputtering, etc. Subsequently, the surfaces of the dielectric layers are processed by chemical-mechanical planarization (CMP). In some embodiments, an opening may be formed by one or more etching processes, and a conductive material may be filled into the opening by deposition steps such as CVD, PVD, and electroplating to form a conductor structure (for example, the conductor structure 25 shown in FIG. 1). In some embodiments, field plates 23 and 26 shown in FIG. 1 may be formed through photolithography, etching, etc. The device obtained through the above process may be similar to the semiconductor device 1 shown in FIG. 1.

As used herein, for ease of description, space-related terms such as “under”, “below”, “lower portion”, “above”, “upper portion”, “lower portion”, “left side”, “right side”, and the like may be used herein to describe a relationship between one component or feature and another component or feature as shown in the figures. In addition to orientation shown in the figures, space-related terms are intended to encompass different orientations of the device in use or operation. A device may be oriented in other ways (rotated 90 degrees or at other orientations), and the space-related descriptors used herein may also be used for explanation accordingly. It should be understood that when a component is “connected” or “coupled” to another component, the component may be directly connected to or coupled to another component, or an intermediate component may exist.

As used in the present disclosure, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all ranges disclosed herein include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

Several embodiments of the present invention and features of details are briefly described above. The embodiments described in the present invention may be easily used as a basis for designing or modifying other processes and structures for realizing the same or similar objectives and/or obtaining the same or similar advantages introduced in the embodiments of the present invention. Such equivalent construction does not depart from the spirit and scope of the present invention, and various variations, replacements, and modifications can be made without departing from the spirit and scope of the present invention.

What is claimed is:

1. A semiconductor device, comprising:
a semiconductor layer;
a first doped nitride semiconductor layer, disposed on the semiconductor layer;
a second doped nitride semiconductor layer, disposed on the first doped nitride semiconductor layer; and
an undoped nitride semiconductor layer between the semiconductor layer and the first doped nitride semiconductor layer, wherein the undoped nitride semiconductor layer has a first surface in contact with the semiconductor layer and a second surface in contact with the first doped nitride semiconductor layer.

2. The semiconductor device according to claim 1, wherein the first doped nitride semiconductor layer is a group IV element-doped nitride semiconductor layer.

3. The semiconductor device according to claim 2, wherein the first doped nitride semiconductor layer is a carbon-doped nitride semiconductor layer.

4. The semiconductor device according to claim 1, wherein the semiconductor layer has a top layer, the top layer contacting the first surface of the undoped nitride semiconductor layer and having the same material as the undoped nitride semiconductor layer.

5. The semiconductor device according to claim 4, wherein the top layer forms an interface with the first surface of the undoped nitride semiconductor layer, the interface having a dislocation extending substantially along the first surface of the undoped nitride semiconductor layer.

6. The semiconductor device according to claim 4, wherein the top layer has a first thickness and the undoped nitride semiconductor layer has a second thickness, the first thickness being less than the second thickness by at least one order of magnitude.

7. The semiconductor device according to claim 6, wherein the first thickness ranges from about 1 nanometer (nm) to about 100 nm.

8. The semiconductor device according to claim 6, wherein the second thickness ranges from about 10 nm to about 1000 nm.

9. The semiconductor device according to claim 1, wherein the semiconductor layer has a top layer, the top layer contacting the first surface of the undoped nitride semiconductor layer and having a material different from a material of the undoped nitride semiconductor layer.

10. The semiconductor device according to claim 9, wherein the top layer forms an interface with the first surface of the undoped nitride semiconductor layer, the interface having a dislocation extending substantially along the first surface of the undoped nitride semiconductor layer.

11. The semiconductor device according to claim 9, wherein the top layer has a first thickness and the undoped nitride semiconductor layer has a second thickness, the first thickness being less than the second thickness by at least one order of magnitude.

12. The semiconductor device according to claim 11, wherein the first thickness ranges from about 1 nm to about 100 nm.

13. The semiconductor device according to claim 11, wherein the second thickness ranges from about 10 nm to about 1000 nm.

14. The semiconductor device according to claim 1, wherein the semiconductor layer is a superlattice layer, the superlattice layer including a plurality of undoped gallium nitride (GaN) layers and a plurality of aluminum gallium nitride (AlGaN) layers.

15. The semiconductor device according to claim 14, wherein the plurality of undoped GaN layers and the plurality of AlGaN layers are alternately stacked.

16. The semiconductor device according to claim 1, wherein the undoped nitride semiconductor layer is an undoped GaN layer.

17. The semiconductor device according to claim 1, wherein the first surface has a first dislocation density and the second surface has a second dislocation density, the second dislocation density being less than the first dislocation density.

18. The semiconductor device according to claim 17, wherein the second dislocation density is less than the first dislocation density by at least one order of magnitude.

19. A method for manufacturing a semiconductor device, comprising:
forming a semiconductor layer on a substrate, wherein the semiconductor layer has a top layer;
forming an undoped nitride semiconductor layer on the top layer of the semiconductor layer; and
forming a doped nitride semiconductor layer on the undoped nitride semiconductor layer.

20. The method according to claim 19, wherein the thickness of the top layer is between about 1 nm and about 100 nm.

21. The method according to claim 19, wherein the thickness of the undoped nitride semiconductor layer is between about 10 nm and about 1000 nm.

22. The method according to claim 19, wherein the semiconductor layer is a superlattice layer comprising a plurality of undoped GaN layers and a plurality of AlGaN layers, the undoped nitride semiconductor layer is an undoped GaN layer, and the doped nitride semiconductor layer is a carbon-doped GaN layer.
